(19) United States
(12) Patent Application Publication
(10) Pub. No.: US 2008/0314430 A1
(43) Pub. Date: Dec. 25, 2008

(54) Line-Voltage-Powered Thermoelectric Device

(76) Inventor: Uttam Ghoshal, Austin, TX (US)

Correspondence Address: ZAGORIN O'BRIEN GRAHAM LLP, 7600B NORTH CAPITAL OF TEXAS HIGHWAY, SUITE 350, AUSTIN, TX, 78731, US

(21) Appl. No.: 12/064,922

(22) PCT Filed: Aug. 25, 2006
(86) PCT No.: PCT/US2006/033336

§ 371 Date: Jul. 14, 2008

Related U.S. Application Data
(60) Provisional application No. 60/711,484, filed on Aug. 26, 2005.

(51) Int. Cl. H01L 35/34; H01L 35/28

(52) U.S. Cl. 136/201; 136/203

(57) ABSTRACT

An apparatus, which may be a heater or cooler, includes a thermoelectric device group having at least one thermoelectric device and an electrical subsystem. The electrical subsystem interfaces the thermoelectric device group to an alternating current (AC) line voltage without utilizing a magnetically coupled structure. In some embodiments the electrical subsystem supplies a rectified signal having a voltage approximately equal to the magnitude of the AC line voltage. In some embodiments the AC line voltage is a standard line voltage of about 90 V to about 250 V.

### TECHNICAL FIELD

The present invention is generally directed to apparatus, methods, and systems including thermoelectric devices and, more particularly, to apparatus, methods, and systems apparatus incorporating line voltage powered thermoelectric devices.

### BACKGROUND ART

Well known commercialized thermoelectric devices (TEDs) are solid-state devices that are based on semiconductor materials that take advantage of the Peltier effect. At room temperature, most TEDs are based on n-doped or p-doped bismuth telluride semiconductor materials. A thermoelectric (TE) element generally consists of a thermoelectric material layer sandwiched between two good conductors, generally metals. These metals act as nearly infinite sources and sinks for carriers: electrons for n-type TE material and holes for p-type TE materials. When carriers are generated at the interface between a metal and a TE material, the metal cools. When carriers recombine at the interface between a metal and a TE material, the metal is heated (absorbs heat). In a p-type TE element, therefore, current enters the metal at the cold side where holes (positively charged current carriers) are generated; they move in the same direction as the current toward the hot side, and recombine there. Current thus flows from the cold side of a p-type TE element to its hot side. Conversely, in an n-type TE element, electrons are generated at the cold side as well, but electrons, bearing a negative charge, flow in the direction opposite to current flow. Current then flows from the hot side of an n-type TE element to its cold side. By arranging TE elements such that p-type and n-type elements alternate and are connected are in an electric series configuration (current enters one TE element, continues through a TE element of opposing type, and so on) while their hot and cold sides are connected in a thermal parallel configuration (hot sides, or junctions, connected by a thermally conductive electrical insulator, and the same for cold sides) one can construct a TED that generates a considerable temperature differential between its hot and cold sides when a unidirectional current flows through the device. By reversing the direction of the current, the hot and cold sides can swap polarities (the hot side becomes the cold side and vice versa).

Traditional bulk TEDs have been built by physically assembling discrete blocks of n-doped or p-doped TE elements onto electrical circuits. The circuits have typically included metal lines, which are formed on ceramic plates, to route the current. The TE elements have typically been placed onto the ceramic plates using pick-and-place assembly equipment and attached to the metal lines on the ceramic plates using solder. Based on this method of manufacturing, the ability to scale the size of TEDs to smaller scales has been limited. Additionally, the use of extensive solder connections in the electrical current path, within a TED, has limited the reliability of the device.

### DISCLOSURE OF INVENTION

Cooling/heating systems utilizing traditional bulk thermoelectric devices (TEDs) typically include a fairly limited number of series-connected thermoelectric devices, and thus require fairly low operating voltages, and utilize power supply subsystems which are capable of generating a fairly low voltage/high current DC output. Such power supplies frequently include a large transformer, high current switching devices, and a wiring harness, in addition to other supporting components. For example, such a power supply might be configured to provide a maximum voltage of about 15 VDC with a maximum current of about 6 A. Such power supply subsystems have increased the cost and weight and reduced the reliability of such thermoelectric systems.

Recently, thermoelectrics have been manufactured based on thin-film materials and wafer-scale integrated circuit (IC) processing. Using IC processing techniques has facilitated smaller thermoelectric feature sizes which provide higher densities and smaller form factors. hi addition, TEDs manufactured in this manner do not use solder to interconnect the thermoelectric elements, as interconnects are achieved using standard IC metal lithography processes. As such, the reliability of a TED employing thin-film thermoelectric structures is generally increased. Smaller, higher-density TEDs also provide several commercial benefits over traditional bulk TEDs. For example, thin-film TEDs exhibit improvements in performance (improved power efficiency, lower cooling/heating times, and better temperature control), reduction in size, and improved reliability as compared to traditional bulk thermoelectrics.

Scaling TEDs to sizes is desirable for several reasons. For example, in a cooling application, the cooling density of a thermoelectric element is inversely proportional to the electrical length of the thermoelectric element. By scaling to smaller geometries, higher cooling densities can be achieved, which allow for cooling the same heat load within a smaller area or, conversely, higher cooling capacities using the same space. Higher cooling densities can also allow for more rapid cooling and better temperature control in various applications. The use of thin-film materials allows the length of a thermoelectric element to be scaled from millimeters down to microns. For example, thin-film thermoelectrics may be manufactured that integrate 1,000 to 16,000 or more thermoelectric “couples” (i.e., complementary pairs of TE elements) per square centimeter.

In addition to the above-enumerated advantages, there remains a heretofore unappreciated benefit of inexpensively being able to integrate a large number of thermoelectric elements (e.g., such as by using wafer-scale integrated circuit processing). By integrating a large number of thermoelectric couples, which are interconnected as a result of such IC processing, a thermoelectric device may be fabricated which can operate using a much higher voltage than before. Moreover, the current required by such a device incorporating large numbers of series-connected thermoelectric couples may be much lower than previous devices, and yet still achieve the same cooling capability. For example, thin-film TEDs may be achieved that are capable of withstanding voltages of 300 V or more (yet still providing good thermal conductivity), while operating at relatively low currents, e.g., 0.5 A.

Because of the large number of such series connected thermoelectric elements required to operate using such high voltages, and due to the high cost and lower reliability of TEDs incorporating such large numbers of thermoelectric elements manufactured using “pick-and-place” technology, the wide availability of power supply circuits providing low voltage, high current outputs, and the historical high cost of thermoelectric devices, it has never before been contemplated to use a line voltage signal to operate a TED. Instead, such systems have previously used power supply systems having transformers and/or other magnetic components which have generally increased the size, weight, and cost of the systems. However, TED-based heating/cooling systems in accordance with the present invention are disclosed that operate directly from a line voltage signal. This affords a reduction in the size, weight, and cost of TED-based heating/cooling systems.

Apparatus, methods, and systems are disclosed herein that can be powered directly by line voltage and that may reduce the size, weight, and cost of TED-based heating/cooling systems. In various embodiments of the present invention an apparatus is configured to include a thermoelectric device which is line voltage powered. Such TEDs allow for a reduction in the size, weight, and cost of power supply and control circuitry, which have otherwise been required to power and control traditional bulk thermoelectric devices. For example, an apparatus incorporating a thin-film TED may be designed that can operate directly from the line voltage. As such, the apparatus does not need to incorporate a relatively large, expensive transformer to step down a line voltage. Eliminating the transformer generally reduces the volume and weight of required peripheral components. Further, lower operating currents (e.g., 0.5 A versus 6 A) facilitate the implementation of lower current-rated, albeit higher voltage-rated, components (e.g., rectifiers, capacitors and conductors) and lower-cost temperature control ICs and printed circuit boards (PCBs), thus allowing for a reduction in system cost.

A thin-film TED may be advantageously incorporated within a wide variety of apparatus, e.g., a bottled water cooler (and/or heater), an insulated container cooler (and/or warmer) such as an “ice chest” replacement, a party tray warmer, a refrigerator, and a water fountain cooler. The line-powered TED may be used in many other apparatus, appliances, and systems, including refrigerators, film coolers, wine coolers, coffee or hot beverage heaters, mug heaters, soda can coolers, soup heaters, hot and cold liquid (e.g., water) dispensers, in which liquid may be cooled by thermally coupling it with the cold side of the TED and liquid may be heated by thermally coupling it with the hot side of the TED. Virtually any instance in which it is desirable to provide cooling and/or heating in an apparatus, and where it is desirable to power the apparatus using a power line voltage which may be convenient, may advantageously employ the line-powered TED described herein.

In one aspect the invention provides an apparatus comprising a thermoelectric device interfaced to an alternating current (AC) line voltage without utilizing a magnetically coupled structure.

In another aspect the invention provides a method of operating a thermoelectric device, the method including receiving an alternating current (AC) line voltage, generating a unipolar line voltage signal derived from the AC line voltage, and coupling at times the unipolar line voltage signal to one or more thermoelectric devices.

In yet another aspect the invention provides an apparatus includes: (1) a thermoelectric device; and (2) means for generating a unipolar line voltage signal derived from an AC line voltage operably coupled thereto, and for coupling, at times, the thermoelectric device to the unipolar line voltage signal.

In still another aspect the invention provides a method for making a product. The method includes forming a power circuit having an input for operably receiving an alternating current (AC) line voltage, said power circuit for operably generating on an output thereof a unipolar line voltage signal derived from the AC line voltage. The method further includes coupling one or more thermoelectric devices to the output of the power circuit.

The invention in several aspects is suitable for TED-based heating/cooling systems, for methods for operating such systems, for methods of making such systems, all as described herein in greater detail and as set forth in the appended claims. The described techniques, structures, and methods may be used alone or in combination with one another.

The foregoing is a summary and thus contains, by necessity, simplifications, generalizations, and omissions of detail. Consequently, those skilled in the art will appreciate that the foregoing summary is illustrative only and that it is not intended to be in any way limiting of the invention. Other aspects, inventive features, and advantages of the present invention, as defined solely by the claims, may be apparent from the detailed description set forth below.

### BRIEF DESCRIPTION OF THE DRAWINGS

The present invention may be better understood, and its numerous objects, features, and advantages made apparent to those skilled in the art by referencing the accompanying drawings.

FIG. 1 is an electrical diagram, in block and schematic form, of an electrical subsystem for a bottled water cooler that incorporates a line voltage powered thermoelectric device (TED).

FIG. 2 shows an exemplary TED group.

FIG. 3 illustrates an electrical circuit incorporating a structure to decouple a TED from an input signal.

FIG. 4 shows an electrical diagram, in block and schematic form, of an alternative electrical subsystem for a bottled water cooler that incorporates a line voltage powered thermoelectric device, a temperature controller, and a voltage filter.

FIG. 5 depicts a simple chiller employing a line-voltage powered TED.

FIG. 6 depicts an alternative configuration for an exemplary chiller employing a line voltage powered TED.

FIG. 7 is a partial exploded view of a relevant portion of an exemplary bottled water cooler.

FIG. 8 illustrates an exemplary system employing a line voltage powered TED to cool one container and heat another.

FIG. 9 shows an exemplary line voltage powered TED array employed to heat one chamber of an insulated chest and cool a second chamber.

The use of the same reference symbols in different drawings indicates similar or identical items.

### MODE(S) FOR CARRYING OUT THE INVENTION(S)

In a prior art bottled water cooling/heating system, a traditional bulk thermoelectric device (TED) is utilized in conjunction with a water reservoir. In this system, a mechanical structure was employed to house an electrical subsystem and a thermal subsystem. When outfitted with the subsystems, the mechanical structure weighed approximately 30 to 50 pounds, cooled the water to about 50° F., and heated the water to about 165° F. (from an ambient temperature of about 75° F.). The electrical subsystem powered various components to cool and heat water and included a power conditioning and temperature control board, a large toroidal transformer (to convert 110 VAC or 220 VAC to a voltage needed to power the bulk thermoelectric), high current metal-oxide semiconductor field-effect transistors (MOSFETs) for switching, and a wiring harness, in addition to other supporting components. In this system, a stepped-down voltage was rectified and filtered to provide a maximum voltage of about 15 VDC with a maximum current of about 6 A. Thus, in this system, the bulk TED required about 90 Watts of power to cool water from a temperature of about 75° F. to a temperature of about 50° F.

The thermal subsystem consisted of a traditional bulk TED having a hot side and a cold side, a hot plate, a cold plate, an ambient heat exchanger, a fan, and wiring for routing power to the TED and the fan (for aiding heat dissipation). The hot side of the TED was coupled to a hot plate, which was thermally coupled to the ambient heat exchanger. The cold plate thermally contacted the cold water reservoir and the cold side of the thermoelectric. The ambient heat exchanger consisted of heat pipes or thermal siphons to carry heat from the hot plate to heat fins, which dissipated heat to ambient air. These prior art systems have required transformers and other magnetic components to step down the line voltage, which have generally increased the size, weight, and cost of the systems.

As used herein, the term “line voltage” (also sometimes called “power line voltage”) refers to an alternating current (AC) voltage generally used for powering appliances, lights, etc, within a home, office, or commercial building. The line voltage magnitude, or amplitude, is typically expressed as the equivalent DC voltage that would be required to deliver the same power to a load. This amplitude is often called the RMS magnitude, or amplitude, because it is calculated by taking the square root (Root) of the average (Mean) of the square (Square) of all the positive and negative voltages in an AC waveform over one period of the waveform. Exemplary line voltages include 110 VAC, 220 VAC, 120 VAC, 208 VAC, and more generally have RMS amplitudes that range from 90 V to over 250 V, typically at 50-60 Hertz.

Such a line voltage may be rectified to produce, for example, a full-wave or half-wave rectified signal. The line voltage rectified signal may be used with or without voltage filtering, and may be directly coupled to the TED without requiring a step-down transformer or other magnetically coupled structure (e.g., a flyback transformer within an AC/DC converter circuit, coupled inductor, etc.). Such a unipolar (i.e., rectified) signal may be selectively switched on and off to control heating or cooling of the TED. Moreover, the polarity of the unipolar signal may be occasionally reversed to afford switchable heating and cooling in the same apparatus. Nonetheless, such a signal is still referred to herein as a unipolar signal.

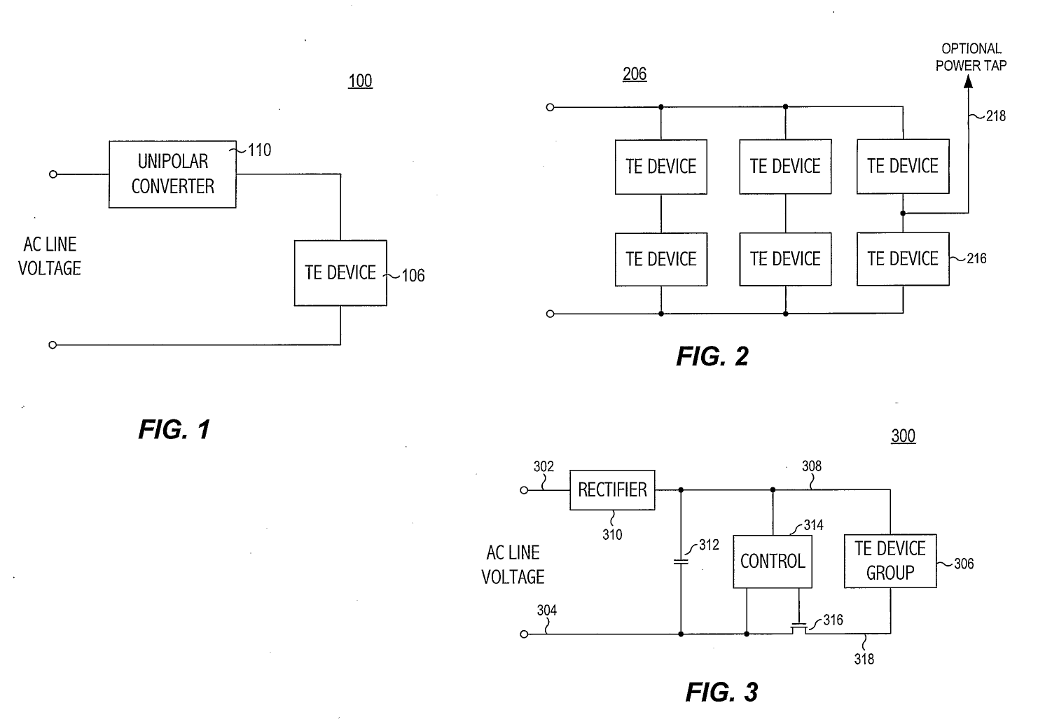

FIG. 1 illustrates an exemplary structure 100 which interfaces a thermoelectric device to an alternating current (AC) line voltage without utilizing a magnetically coupled structure. The AC line voltage is provided as an input to the subsystem 100. The subsystem 100 employs a unipolar converter circuit 110 to convert the line voltage to a unipolar signal, which is then supplied to the TED 106. No magnet or magnetically coupled structure is required, and none appears in the example of FIG. 1. It should be appreciated that many conversion techniques, e.g., full- or half-wave rectification, may be employed in an electrical subsystem configured according to the present invention. Other configurations of an electrical subsystem may, of course, be employed without departing from the teaching herein. Due to the difference in time scale between electrical response to an electrical disturbance and thermal response to a resulting thermal disturbance, the performance of the system is relatively robust to the quality (or lack thereof) of the input voltage. Even brief disruptions in rectification degrade the cooling ability of the system only slightly over the time scale of interest.

Exemplary TEDs which may be advantageously employed in certain embodiments of this invention are described in U.S. Patent Application Publication No. 2006/0076046, entitled “THERMOELECTRIC DEVICE STRUCTURE AND APPARATUS INCORPORATING SAME” by Uttam Ghoshal, et al., the disclosure of which is hereby incorporated by reference in its entirety, and also described in U.S. Patent Application Publication No. 2006/0150539, entitled “MONOLITHIC THIN-FILM THERMOELECTRIC DEVICE INCLUDING COMPLEMENTARY THERMOELECTRIC MATERIALS” by Srikanth B. Samavedam, et al., the disclosure of which is hereby incorporated by reference in its entirety.

It may be convenient for some applications to use a group of TEDs rather than a single device. FIG. 2 shows an example of such a group 206. In this example individual TEDs 216 are connected in series and parallel configurations to form the group 206. While three parallel sets of two series-connected TEDs are shown, other configurations are contemplated, including larger numbers of series-connected devices, whether alone or in parallel with other devices. For example, 16 such series connected TEDs may be implemented in a physical 4×4 array to provide a large area cooling capacity, and may incorporate 16,000 thermoelectric couples, which are connected in series and impressed with a rectified line voltage (or other unipolar) signal thereacross. Also shown is a “tap” voltage taken from an intermediate node 218 between certain ones of the series connected TEDs. Such a tap voltage signal, which may be chosen as having a fairly low voltage (e.g., 12 V) relative to the rectified line voltage, may be useful for providing a lower magnitude power signal to other components, such as control circuitry, fans, etc., as described elsewhere herein.

FIG. 3 illustrates another exemplary power circuit 300 which includes a control circuit 314 to selectively decouple a group of TEDs 306 from a unipolar signal when desired. Here an AC line voltage coupled to input terminals 302, 304 is converted by a rectifier 310 to generate a unipolar output signal on node 308. Capacitor 312 is included to provide filtering for the unipolar signal conveyed on node 308. The control circuit 314 which, for example, may be responsive to a temperature sensor (not shown), is configured to turn on transistor 316 to couple node 318 to the input terminal node 304, and thus couple the TED group 306 to the unipolar signal (i.e., the voltage developed between nodes 308 and 304), and conversely to turn off transistor 316 to decouple the TED group 306 from the unipolar signal.

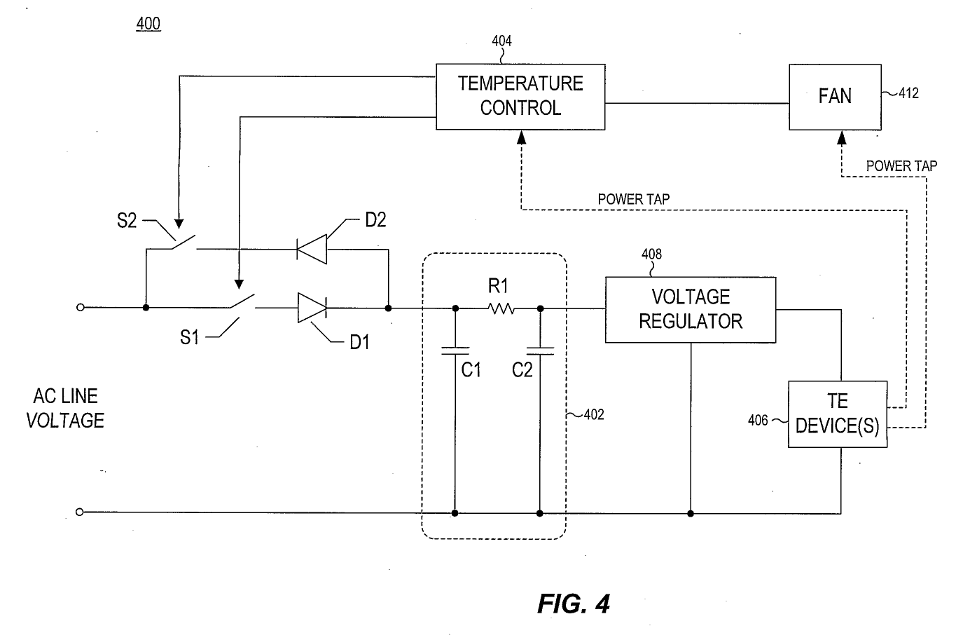

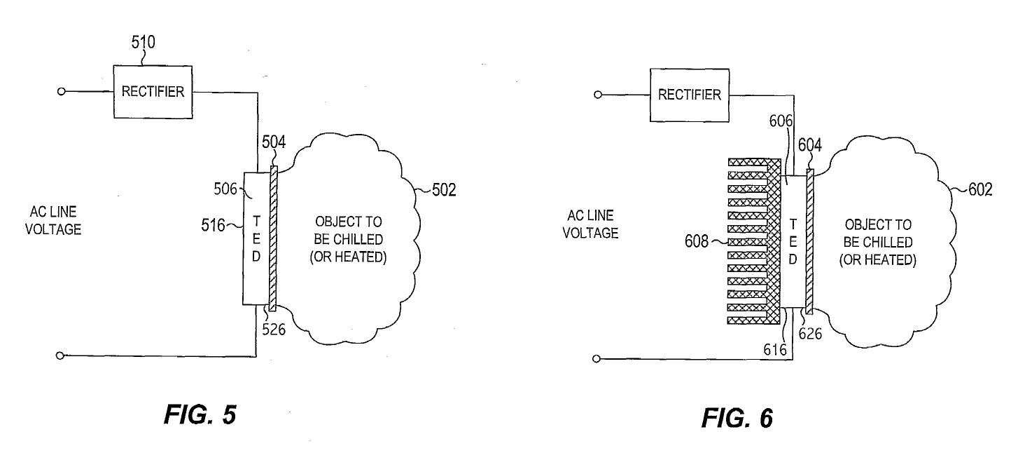

FIG. 4 illustrates an exemplary electrical subsystem 400 incorporating a TED 406, which may be implemented as part of a cooler such as is depicted in FIGS. 5 and 6. In this example, an AC line voltage is provided as an input to the subsystem 400. The subsystem 400 employs half-wave rectification of the line voltage, without utilizing a magnetically coupled structure for down-converting the voltage. It should be appreciated that other rectification techniques, e.g., full-wave rectification and bridge rectification, may be employed in an electrical subsystem configured according to the present invention. In this embodiment, a temperature control 404 monitors the temperature of an object or structure to be cooled (not shown here; refer to FIGS. 5 and 6) and, based upon the monitored temperature, determines whether adjustment is required. Suitable temperature control 404 circuits are widely available, including from Maxim Integrated Products, Inc., Sunnyvale, Calif. The temperature control 404 may, for example, cause power to be removed from the TED 406 by providing a control signal that causes switches S1 and S2 to become non-conductive, thus, disconnecting the TED 406 from its power source. The switches S1 and S2 may be, for example, enhancement-mode field-effect transistors (FETs).

The temperature control 404 may also cause the TED 406 to cool a structure by causing switch S1 to become conductive and switch S2 to become or remain non-conductive. Similarly, the temperature control 404 may, in certain applications, also cause the TED 406 to warm the structure by causing switch S2 to become conductive and switch S1 to become or remain non-conductive. The electrical subsystem 400 may implement a filter 402, including resistor R1 and capacitors C1 and C2, to filter the half-wave rectified (by diodes D1 or D2) voltage. Alternatively, the filter 402 may take a different form using non-magnetically coupled structures or may not be implemented. In certain applications it may also be desirable to implement a voltage regulator 408 to provide improved regulation of the voltage supplied to the TED 406. The temperature control 404 may also control operation of fan 412, based on a sensed temperature. Alternatively, the fan 412 may run continuously or be controlled to operate periodically. While power leads for the temperature control 404 and fan 412 are not fully shown (for clarity), such power leads may be implemented as one or more separate “tap” voltages taken from intermediate nodes between series-connected TEDs within the TED 406, as more fully shown and described in regards to FIG. 2.

FIG. 5 depicts a simple chiller employing a line-voltage powered TED. An incoming line voltage, converted to a unipolar signal by rectifier 510, powers a TED 506, which develops a temperature differential between its hot 516 and cold 526 sides. To chill an object 502, the object 502 is thermally coupled to the cold side 526 of the TED 506. This coupling may be direct or, as illustrated in FIG. 5, by means of a thermal coupler 504. The thermal coupler 504 may be a solid thermal conductor, e.g. diamond or metal, or a thermal paste, or a solder, or a heat pipe, or a liquid metal thermal conduction device, or any of a number of devices or systems capable of conducting heat between the TED 506 and the object to be chilled 502. It may improve the efficiency of the system to employ thermal couplers that conduct heat efficiently such that the temperature at the cold side 526 of the TED 506 is nearly equal to the temperature of the object 502.

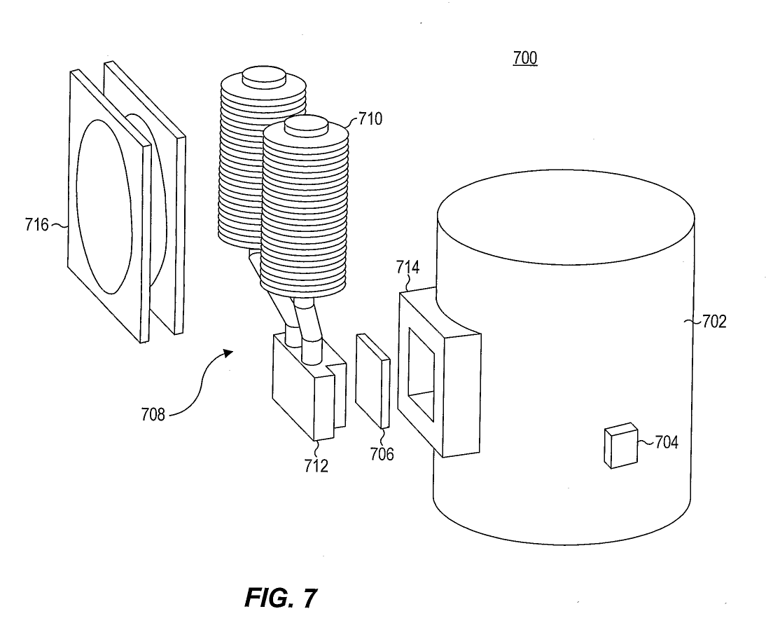

If desired, a mechanism for dissipating excess heat at the hot side of the TED may be added to the system. FIG. 6 depicts such a system. In this example a solid-air heat exchanger 608 has been mounted to the hot side 616 of the TED 606 whose cold side 626 is in thermal contact with the chilled object 602 via optional thermal coupler 604. Other heat dissipaters 608 may be heat spreaders with or without cooling fins, evaporators, solid-fluid heat exchangers, cooling fins with fans for moving air or liquid through the fins, and many other heat dissipating devices and systems. A relatively sophisticated system as applied to a bottled water cooler is depicted in FIG. 7.

With reference to FIG. 7, a relevant portion of an exemplary bottled water cooler 700 is illustrated. The cooler 700 includes a water reservoir 702 which contains water to be cooled and/or heated. A temperature control 704 is integrated along an outer sidewall of the reservoir 702 to sense the temperature of water inside the reservoir 702 and to control the TED 706 accordingly. The cold side of TED 706 is positioned within a cavity formed in a housing 714, integrated with the sidewall of the reservoir 702, in thermal contact with the sidewall of the reservoir 702. A portion of a heat exchanger 708 (depicted here as including a cooler evaporator 712), is positioned within the cavity in thermal contact with the hot side of the TED 706. The heat exchanger 708 may also include one or more cooler condensers 710 extending from the cooler evaporator 712. The condensers 710 may include a plurality of heat fins that aid in the dissipation of heat to ambient air. An optional fan 716 may be positioned to blow air across the heat fins of the condensers 710 to increase heat transfer to the ambient air.

Other configurations of the bottled water cooler 700 are, of course, possible. For example, the TED 706 may not need a housing 714, particularly when it can be directly attached to or incorporated into the wall of the reservoir 702. The TED 706 may be coupled to the heat exchanger 708 through intermediate subsystems, such as heat pipes, liquid (including liquid metal) cooling loops, or thermally conductive plates. The heat exchanger 708 may not employ condensers 710 and rely solely on heat fins or other heat dissipating structures. Heat may be exhausted from the system into a liquid reservoir, rather than directly into air. In some applications, such as a bottled water dispenser that dispenses both hot and cold water, heat from the hot side of the TED may be used to heat, or help heat, liquid in another reservoir. In some configurations, multiple TEDs may be used, in series or parallel configurations, to increase the cooling (or heating, as required) capacity of the apparatus. Certain exemplary embodiments of a bottled water cooler are also described in U.S. Provisional Patent Application Ser. No. 60/711,484, filed Aug. 26, 2005, the entire disclosure of which is hereby incorporated herein by reference in its entirety for all purposes.

FIG. 8 illustrates an embodiment wherein the TED cools one container and heats another. In the heater/chiller of FIG. 8, a structure to be cooled 802, e.g. a cold container, is cooled by a TED 806 which may be powered by a line voltage, such as from a household outlet (not shown). The TED 806 may be a set of many TEDs, as depicted in FIG. 2, and if desirable or useful (for this or any other embodiment), may be arranged to create one or more multistage devices (i.e., to achieve a higher differential temperature between hot and cold sides). The TED 806 may be thermally coupled to the cold structure 802 by one or several intervening thermal conductors 804 as depicted, or the TED 806 may be mounted with its cold side directly contacting the structure 802. Heat dissipated from the hot side of TED 806 is thermally coupled by thermal coupler 818 to a structure to be heated 822, e.g. a hot container, which is thermally insulated from the cold structure 802. Thermal couplers 804 and 818 may be heat pipes, solid metal, liquid metal suitably sheathed, ceramic thermal conductors, etc. run from one side of the TED 806 to the respective structure. When a line voltage is applied to the TED, the cold structure 802 is chilled while the excess heat generated as a byproduct is used to heat the hot structure 822. When the structures are containers, the contents of the cold container 802 are chilled while the contents of the hot container 822 are heated.

While FIG. 8 has been described as having the cold side of the TED 806 in thermal contact with the cold container, by reversing the polarity of the supplied voltage, the TED 806 reverses its thermal polarity such that now the hot side is in thermal contact with a container (802) that is being warmed, while the now cold side is thermally connected to a container (822) that is now being chilled.

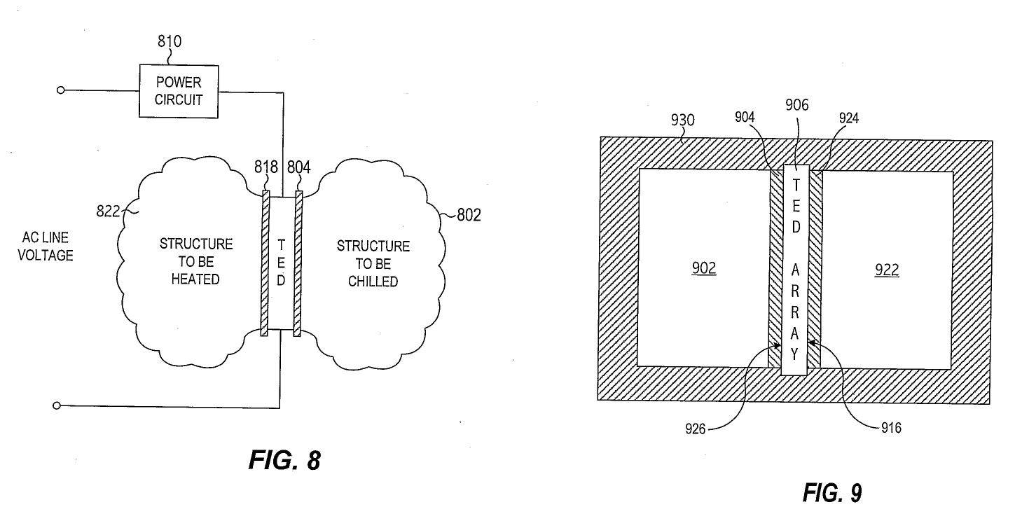

An application of the concepts explained with reference to FIG. 8 is depicted in FIG. 9. A picnic chest 900 has a cold chamber 902 and a warm chamber 922 separated by thermal insulation 930. A TED array 906 is situated between the chambers 902, 922 such that its cold side 926 is in thermal contact with the cold chamber 902 by way of thermal conductor 904, and its hot side 916 is in thermal contact with the warm chamber 922 by way of thermal conductor 924. An optional temperature control (not shown) may be used to adjust the temperatures of each chamber separately, or to maintain a particular temperature difference between them, as desired. Though described with reference to a “picnic chest,” those skilled in the art will no doubt recognize, from the description herein, the utility of such a system in other applications, such as laboratory storage for specimens requiring different temperatures, a refrigerator/warmer-cooker combination, or an apparatus for vending both heated and chilled foods or beverages whether dispensed automatically by a machine or interactively by a human vendor.

An apparatus has been described herein that includes a TED that interfaces directly to line voltage without utilizing a magnetically coupled structure. Such an apparatus is relatively economical to produce and operate, and when taking the form of a bottled water cooler is generally smaller in size and lighter in weight than other commercially available bottled water coolers. For clarity of description, specific applications of line-powered TEDs have been discussed. The use of a specific example for the purpose of explanation should not be construed to limit the scope of the invention in any way.

As used herein, coupling is intended to include both direct and indirect coupling. Consequently, intervening elements may be disposed between coupled-together elements, but not directly coupled together elements.

While the invention has been described with reference to various realizations, it will be understood that these realizations are illustrative and that the scope of the invention is not limited to them. Many variations, modifications, additions, and improvements are possible. More generally, realizations in accordance with the present invention have been described in the context of particular realizations. Functionality may be separated or combined in blocks differently in various realizations of the invention or described with different terminology. As used herein, plural instances may be provided for components described herein as a single instance. These and other variations, modifications, additions, and improvements may fall within the scope of the invention as defined in the claims that follow.

1. An apparatus comprising a thermoelectric device interfaced to an alternating current (AC) line voltage without utilizing a magnetically coupled structure.

2. The apparatus of claim 1 further comprising a second thermoelectric device electrically coupled in series with the first mentioned thermoelectric device and thermally coupled in parallel with the first mentioned thermoelectric device.

3. The apparatus of claim 1 further comprising a power circuit operable to provide a unipolar signal derived from the AC line voltage to the thermoelectric device.

4. The apparatus of claim 3 wherein the power circuit is configured to selectively decouple, at times, the thermoelectric device from the unipolar signal.

5. The apparatus of claim 3 wherein the power circuit is configured to selectively reverse the polarity of the unipolar signal.

6. The apparatus of claim 3 wherein the AC line voltage has an RMS magnitude of about 90 VAC to about 250 VAC.

7. The apparatus of claim 3 wherein:
the power circuit comprises a rectifying circuit coupled directly to the AC line voltage operably provided thereto, said rectifying circuit for generating a rectified line voltage signal on an output thereof;
wherein the thermoelectric device is coupled directly to the output of the rectifying circuit.

8. The apparatus of claim 7 wherein the rectified line voltage signal has a peak amplitude at least as large as the RMS voltage of the AC line voltage.

9. The apparatus of claim 1 wherein the thermoelectric device comprises a thin-film thermoelectric device.

10. The apparatus of claim 1 further comprising:
an object thermally coupled to the thermoelectric device.

11. The apparatus of claim 10 wherein:
the object comprises a reservoir for holding a liquid.

12. The apparatus of claim 11 wherein the apparatus comprises a bottled water cooler or a water fountain cooler.

13. A method of operating a thermoelectric device, the method comprising:
receiving an alternating current (AC) line voltage;
generating a unipolar line voltage signal derived from the AC line voltage; and
coupling at times the unipolar line voltage signal to one or more thermoelectric devices.

14. The method of claim 13 wherein the AC line voltage has an RMS magnitude of about 90 VAC to about 250 VAC.

15. The method of claim 13 wherein the unipolar line voltage signal has a peak amplitude at least as large as the RMS voltage of the AC line voltage.

16. The method of claim 13 wherein the unipolar line voltage signal is generated without utilizing any magnetically coupled structures.

17. The method of claim 13 further comprising, at times, reversing the polarity of the unipolar line voltage signal.

18. The method of claim 13 wherein said one or more thermoelectric devices comprises a thin-film thermoelectric device.

19. The method of claim 13 wherein:
said generating a unipolar line voltage signal comprises coupling a rectifying circuit directly to the AC line voltage, and generating a rectified line voltage signal on an output thereof; and
said coupling at times the unipolar line voltage signal to one or more thermoelectric devices comprises coupling, at times, the thermoelectric device directly to the output of the rectifying circuit.

20. The method of claim 13 further comprising:
thermally coupling an object to be heated and/or cooled to the thermoelectric device.

21. An apparatus comprising:
a thermoelectric device;
means for generating a unipolar line voltage signal derived from an AC line voltage operably coupled thereto, and for coupling, at times, the thermoelectric device to the unipolar line voltage signal.

22. The apparatus of claim 21 wherein said means is configured to selectively decouple, at times, the thermoelectric device from the unipolar signal.

23. The apparatus of claim 21 wherein said means is configured to selectively reverse the polarity of the unipolar signal.

24. The apparatus of claim 21 wherein the AC line voltage has an RMS magnitude of about 90 VAC to about 250 VAC.

25. The apparatus of claim 21 wherein the unipolar signal has a peak amplitude at least as large as the RMS voltage of the AC line voltage.

26. A method for making a product, the method comprising:
forming a power circuit having an input for operably receiving an alternating current (AC) line voltage, said power circuit for operably generating on an output thereof a unipolar line voltage signal derived from the AC line voltage; and
coupling one or more thermoelectric devices to the output of the power circuit.

27. The method of claim 26 wherein the power circuit includes no magnetically coupled structures.

28. The method of claim 26 wherein the power circuit is configured to operate with an AC line voltage having an RMS magnitude of about 90 VAC to about 250 VAC.

29. The method of claim 26 further comprising:
thermally coupling an object to be heated and/or cooled to said one or more thermoelectric devices.

30. The method of claim 26 wherein each thermoelectric device comprises a thin-film thermoelectric device.
